(19) United States
(12) Patent Application Publication
(10) Pub. No.: US 2025/0383386 A1
(43) Pub. Date: Dec. 18, 2025

(54) METHODS OF DETECTING ELECTROMAGNETIC FIELDS, AND SYSTEMS IMPLEMENTING THE SAME

(71) Applicant: ROWAN UNIVERSITY, Glassboro, NJ (US)

(72) Inventor: Michael J. LIM, Ardmore, PA (US)

(73) Assignee: ROWAN UNIVERSITY, Glassboro, NJ (US)

(21) Appl. No.: 18/875,833

(22) PCT Filed: Jun. 16, 2023
(86) PCT No.: PCT/US23/25608

§ 371 Date: Dec. 17, 2024

Related U.S. Application Data
(60) Provisional application No. 63/353,589, filed on Jun. 18, 2022.
(60) Provisional application No. 63/417,821, filed on Oct. 20, 2022.

(51) Int. Cl. G01R 29/08

(52) U.S. Cl. CPC G01R 29/0885

(57) ABSTRACT

A method of detection of electromagnetic fields is provided. The method includes the steps of: providing a first beam in a first direction through a vapor cell, the first beam having a frequency ωₚ; providing a second beam in a second direction through the vapor cell, the second beam having a frequency ω_{d}; providing a third beam in the second direction through the vapor cell, the third beam having a frequency Ω_{c}; frequency stabilizing the first beam, the second beam, and the third beam to successive stepwise resonant transitions resulting in the excitation of a Rydberg state; applying symmetrical radio frequency sidebands to the third beam, the symmetrical RF sidebands with frequency spacing ω_{RF} from Φ_{c;}coherently transferring the symmetrical RF sidebands to the first beam via a nonlinear wave mixing in the vapor cell; and determining an electromagnetic field inside the vapor cell.

### CROSS-REFERENCE TO RELATED APPLICATIONS

The present application claims priority to U.S. Provisional Patent Application No. 63/353,589, filed Jun. 18, 2022, and U.S. Provisional Patent Application No. 63/417,821, filed Oct. 20, 2022, both of which are incorporated herein by reference in their entirety.

### BACKGROUND

Rydberg atoms can be useful for their innate sensitivity to electromagnetic (EM) fields. However, prior art has focused on using the phenomenon of Electromagnetically Induced Transparency (EIT) to engineer efficient detection of radiofrequency (RF) electric fields (>10 MHz). Present EM detection methods, including EIT detection methods, would benefit from inherently lower noise floors and are generally less sensitive for detection of ultra-low frequencies.

Thus, it would be desirable to provide improved methods of detection of EM fields with greater intrinsic sensitivity at low frequencies.

### SUMMARY

One aspect of the present disclosure provides a method of detection of electromagnetic fields. The method includes the steps of: (a) providing a first beam in a first direction through a vapor cell, the first beam being a probe beam, the first beam having a frequency ωₚ; (b) providing a second beam in a second direction through the vapor cell, the second beam being a dressing beam, the second beam having a frequency ω_{d}; (c) providing a third beam in the second direction through the vapor cell, the third beam being a coupling beam, the third beam having a frequency ω_{c}, the third beam being coaxial with both the first beam and the second beam; (d) frequency stabilizing the first beam, the second beam, and the third beam to successive stepwise resonant transitions resulting in the excitation of a Rydberg state; (e) applying symmetrical radio frequency (RF) sidebands to the third beam, the symmetrical RF sidebands with frequency spacing ω_{RF} from ω_{c}; (f) coherently transferring the symmetrical RF sidebands to the first beam via a nonlinear wave mixing in the vapor cell; and (g) determining an electromagnetic field inside the vapor cell.

Another aspect of the present disclosure provides a system for detection of electromagnetic fields. The system includes a first laser source configured to provide a first beam, the first beam being a probe beam. The system also includes a second laser source configured to provide a second beam, the second beam being a dressing beam. The system also includes a third laser source configured to provide a third beam, the third beam being a coupling beam. The system also includes a vapor cell, the vapor cell being configured to contain a gaseous alkali element. The system also includes a first dichroic mirror configured to combine the second beam and the third beam. The system also includes a second dichroic mirror configured to allow the first beam to pass through, while reflecting the second beam and the third beam. The system also includes a third dichroic mirror configured to allow the second beam and the third beam to pass through while reflecting the first beam. The system also includes a plurality of signal processing components configured to analyze an electrical signal of the first beam.

Another aspect of the present disclosure provides another method of detection of electromagnetic fields. The method includes the steps of: (a) providing a first beam in a first direction through a vapor cell, the first beam being a probe beam, the first beam having a frequency ωₚ; (b) providing a second beam in a second direction through the vapor cell, the second beam being a dressing beam, the second beam having a frequency ω_{d}; (c) providing a third beam in the second direction through the vapor cell, the third beam being a coupling beam, the third beam having a frequency ω_{c}, the third beam being coaxial with both the first beam and the second beam; (d) frequency stabilizing the first beam, the second beam, and the third beam to successive stepwise resonant transitions resulting in the excitation of a Rydberg state; (e) applying a modulation electric field at frequency ωₘ to the vapor cell using electrodes; (f) beating together all optical frequencies contained in the probe beam after transiting through the vapor cell, by focusing it onto a photodiode; (g) demodulating a photodiode signal at ωₘ; and (h) determining an electromagnetic field near the vapor cell.

Another aspect of the present disclosure provides another system for detection of electromagnetic fields configured to implement methods of the present disclosure. The system includes a first laser source configured to provide a first beam, the first beam being a probe beam. The system also includes a second laser source configured to provide a second beam, the second beam being a dressing beam. The system also includes a third laser source configured to provide a third beam, the third beam being a coupling beam. The system also includes a vapor cell, the vapor cell being configured to contain a gaseous alkali element. The system also includes a first dichroic mirror configured to combine the second beam and the third beam. The system also includes a second dichroic mirror configured to allow the first beam to pass through, while reflecting the second beam and the third beam. The system also includes a third dichroic mirror configured to allow the second beam and the third beam to pass through while reflecting the first beam. The system also includes a plurality of signal processing components configured to analyze an electrical signal of the first beam. The plurality of signal processing components includes a lock-in amplifier.

### DEFINITIONS

The instant invention is most clearly understood with reference to the following definitions.

As used herein, the singular form “a,” “an,” and “the” include plural references unless the context clearly dictates otherwise.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from context, all numerical values provided herein are modified by the term about.

As used in the specification and claims, the terms “comprises,” “comprising,” “containing,” “having,” and the like can have the meaning ascribed to them in U.S. patent law and can mean “includes,” “including,” and the like.

Unless specifically stated or obvious from context, the term “or,” as used herein, is understood to be inclusive.

Ranges provided herein are understood to be shorthand for all of the values within the range. For example, a range of 1 to 50 is understood to include any number, combination of numbers, or sub-range from the group consisting 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 (as well as fractions thereof unless the context clearly dictates otherwise).

### BRIEF DESCRIPTION OF THE DRAWINGS

For a fuller understanding of the nature and desired objects of the present invention, reference is made to the following detailed description taken in conjunction with the accompanying drawing figures wherein like reference characters denote corresponding parts throughout the several views.

FIG. 1 illustrates an energy diagram showing one of several possible Modulation Transfer Spectroscopy (MTS) processes.

FIG. 2 illustrates a schematic layout of a system, in accordance with an exemplary embodiment of the present disclosure.

FIG. 3A illustrates an EIT signal with a coupling laser frequency scan across the 60F5/2 resonance (with a 500 Hz electric field at 640 mV/m applied to atoms in a vapor cell).

FIG. 3B illustrates a recorded MTS signal from the same cell and laser beam configuration as FIG. 3A, with a shaded area highlighting the part of the MTS spectrum sensitive to an electric field.

FIG. 4 illustrates typical EIT signals for calibrating frequency-dependent Faraday shielding inside an exemplary rubidium vapor cell.

FIG. 5 illustrates frequency-dependent Faraday screening data with fit to two characteristic cutoff frequencies.

FIG. 6 illustrates an MTS electrometer response to a one (1) kHz reference field

$$( with \text{intra-cell} amplitude of 114 \frac{mV}{m} / \sqrt{Hz} ) .$$

FIG. 7 illustrates a flow chart for implementing a general receiver in the ULF frequency range using MTS electrometry.

FIG. 8 illustrates a schematic layout of another system, in accordance with an exemplary embodiment of the present disclosure.

FIG. 9 illustrates a specialized vapor cell with internal field plates spaced by 0.5 cm.

FIG. 10 illustrates an open electrode configuration for producing the modulation E-field. The cell rests on the bottom aluminum plate, which is held at electrical ground; the rods above the cell are driven with an 11 kHz sinusoidal voltage of amplitude Vₘ. The bias E-field is produced by applying voltage V_{b} to a large top plate (not shown) located 13 cm above the bottom plate.

FIGS. 11A-11I illustrate lock-in amplifier outputs vs. coupling laser frequency, recorded while a static bias field is applied; values range from a) −1.7V/m to i) +1.7V/m. Each panel shows magnitude (R) in dark traces and simultaneously measured phase (θ) in light traces. As described in the text, θ exhibits a drop (a-f) or rise (g-i) that coincides with the cusp in R. Both magnitude and phase exhibit sensitivity to the sign of the applied field.

FIG. 12 illustrates a graphical representation of signal vs. coupling laser frequency, recorded while a 100 Hz oscillating bias field with amplitude E_{b}=0.72V/m is applied. The coupling laser scan time is 1 s.

FIG. 13 illustrates Fast Fourier Transform (FFT) of X-output, averaged over 50 s while a 10 Hz bias field with amplitude E_{b}=0.20V/m is applied.

FIG. 14A illustrates oscillating bias voltage applied at 4.7 Hz, producing field amplitude of E_{b}=0.03V/m. Measured applied voltage (light trace) is illustrated with a sinusoidal fit (dark trace).

FIG. 14B illustrates measured X-output signal of LIA (light trace) with a fitted sinusoidal response (dark trace) with an amplitude of fit of 16 mV.

FIG. 15 illustrates a Fast Fourier Transform (FFT) of X-output, averaged over 100 s while a 76 Hz bias field with amplitude E_{b}=3.8V/m is applied via the external electrodes.

FIG. 16 illustrates a Schematic of alkali vapor cell (center) surrounded by proposed open electrode structure to apply three mutually perpendicular modulation E-fields. Rods on the left half of the cube are at electrical ground; each remaining pair of parallel rods can be used to independently apply a modulation field at an arbitrary frequency.

FIG. 17A illustrates 10 Hz FM and AM response. In this demonstration, two large parallel metal plates were used as external electrodes, with Vₘ applied to the top plate. a) Time-varying V_{b} waveform applied to bottom plate; the frequency is modulated between 0.1-1.9kHz, while the amplitude is modulated by 85%.

FIG. 17B illustrates X-output signal Vₛ showing response to varying amplitude and frequency of the bias voltage. The low-frequency response is attenuated by Faraday screening due to the metallic rubidium layer on the vapor cell inner wall.

FIGS. 18A-18B illustrate experimental setups, useful in demonstrating certain embodiments of the present disclosure.

FIGS. 19-20 illustrate experimental setups, useful in demonstrating certain embodiments of the present disclosure.

FIGS. 21-23 illustrate flow diagrams of method of detection of electromagnetic fields, in accordance with certain exemplary embodiments of the present disclosure.

### DETAILED DESCRIPTION

The present disclosure provides a novel method for three-color detection of atomic Rydberg states within a vapor cell. The present disclosure further provides Modulation Transfer Spectroscopy (MTS) implemented in a four-level system, driven by three lasers in a ladder-type configuration, wherein each laser is tuned to a resonant transition.

The present disclosure provides a novel method for ultra-sensitive detection of weak, low-frequency electric fields. Such a method is applicable to a variety of applications, including underwater communication with submarines, ground-to-satellite communication, and subterranean mapping. A method described in the present disclosure uses lasers to detect changes in the properties of highly excited quantum states (e.g., Rydberg states) caused by weak ambient electric fields in the ultra-low frequency (ULF) (e.g., 300-3000 Hz) and very low frequency (VLF) (e.g., 3-30 kHz) ranges. Rydberg atoms can be useful for their innate sensitivity to electromagnetic (EM) fields. The phenomenon of Electromagnetically Induced Transparency (EIT) has been used to engineer efficient detection of radiofrequency (RF) electric fields (e.g., >10 MHz). Certain embodiments of the present disclosure can be described as Modulation Transfer Spectroscopy (MTS). The use of MTS can achieve greater intrinsic sensitivity at much lower frequencies (e.g., as compared to the use of EIT). An MTS receiver of the present disclosure can detect a one (1) kHz electric field with a noise floor orders of magnitude (e.g., two or more) lower than the most sensitive EIT-based receiver in this frequency range. In certain embodiments, Modulation Transfer Spectroscopy (MTS) can be expanded and adapted such that an atomic AM-receiver for ULF and VLF fields has intrinsic sensitivity at these low frequencies.

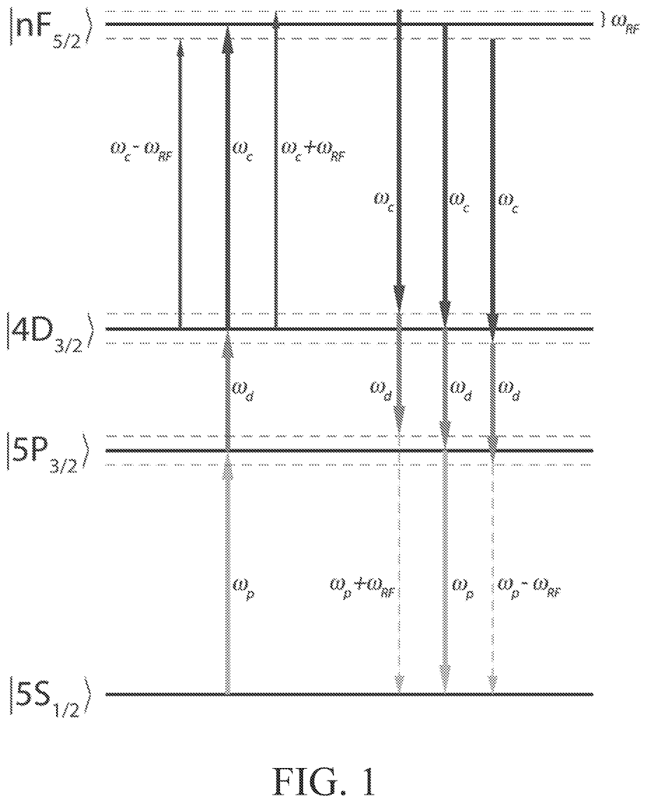

In certain embodiments of the present disclosure, a method using an MTS technique can utilize a six-wave mixing (6 WM) mechanism that depends on both stimulated absorption and stimulated emission. As illustrated in the energy level diagram of FIG. 1, certain the methods of the present disclosure employ three near-infrared laser frequencies to sample a Rydberg state in atomic rubidium: a first beam (i.e., a “probe” beam) at wavelength of 780 nm (ωₚ), a second beam (i.e., a “dressing” beam) at 1529 nm (ω_{d}), and a third beam (i.e., a “coupling” beam) in the vicinity of 700 nm (ω_{c}). The exact wavelength of the coupling laser depends on the particular Rydberg state addressed. For example, the coupling laser can excite the n=60 state at a wavelength of 699 nm. Among several possible mixing processes, one process can be described in connection with FIG. 1.

Referring now to FIG. 1, an energy diagram is illustrated showing one of several possible MTS processes of the present disclosure. A probe laser and a dressing laser are frequency-stabilized to their respective atomic transitions. Approximately 10% RF sidebands (i.e., at ω_{RF}˜2π×10MHz) are applied to the near-resonant coupling laser beam. When the coupling laser is on (or sweeps across), the upper atomic resonance (4D_{3/2}→60F_{5/2}), photons are absorbed at ωₚ and ω_{d} (see thick upward arrows), as well as ω_{c}-ω_{RF} or ω_{c}+ω_{RF} (thin upward arrows connecting to virtual energy levels denoted by black dashed lines). Simultaneously, photons are coherently emitted at ω_{c} and ω_{d} (see thick downward arrows), as well as at completely new frequencies, ωₚ+ω_{RF} and ωₚ-ω_{RF} (see thin dashed downward arrows). The photons created at these new frequencies are products of a 6-wave mixing (6 WM) process that conserves both energy and momentum. Effectively, the frequency sidebands are coherently transferred from the coupling laser to the probe laser when all atomic transitions are resonantly driven. Due to the large physical extent of the 60F_{5/2} atomic orbital, this quantum state is easily perturbed by ambient, low-frequency electric field, which in turn affects the coherent transfer of the frequency sidebands. A fast readout of such an effect can be accomplished by interfering the probe laser carrier frequency with its acquired sidebands on a fast photodiode and measuring the phase of the resulting beat note.

FIG. 1 shows a laser excitation scheme used in a four-level atomic system. The probe laser (e.g., Photodigm PH780DBR040T8) at ωₚ=2p c/780 nm is frequency-stabilized to the 5S_{1/2} (F=3)→5P_{3/2} (F′=4) transition and the dressing laser (e.g., NEC NX8563LA303) at ω_{d}=2πc/1529 nm is frequency-stabilized to the 5P_{3/2} (F′=4)→4D_{3/2} (F″=3) transition of a ⁸⁵Rb isotope. The probe laser and dressing laser can both be monolithic, single-frequency diode lasers. The dressing laser seeds a fiber amplifier (e.g., Amonics AEDFA-C-PM-700); its output is dispersed with a diffraction grating to filter out background amplified spontaneous emission from the laser line. The coupling laser (e.g., Coherent MBR-110) at ω_{c}=2πc/λ_{c} can be a tunable Ti: sapphire ring laser, stabilized to a reference cavity. Tuning λ_{c} in the wavelength range 745 nm-698 nm enables access to nF_{5/2} states, with n=11-70; sidebands at ω_{c}±ω_{RF} are generated with an electro-optic modulator (EOM).

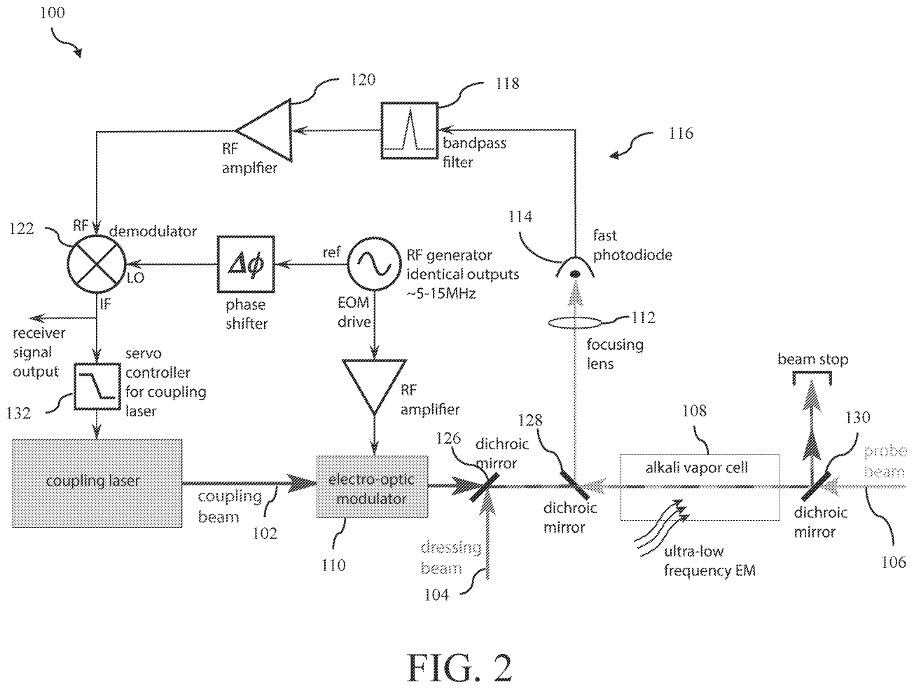

The probe and dressing lasers can be independently frequency-stabilized to their respective resonant transitions in a vapor cell containing natural isotopic mixture of atomic rubidium. Such a vapor cell can be dedicated to frequency locking. Three-color measurements can be performed in a second, separate, vapor cell. To frequency lock lasers, a single electro-optic modulator (e.g., New Focus 4002) can be used and simultaneously driven at two frequency values lacking a common factor, to generate two pairs of frequency sidebands on a strong 780-nm beam that is sent through the cell. Separate error signals can be derived for each laser by counterpropagating two weak beams: one at 780 nm and another at 1529 nm, with all beams coaxially overlapped. The beat note signals from the two weak beams are demodulated at the two different modulation frequencies and low-pass filtered to generate error signals for frequency stabilization. In certain embodiments, the probe and dressing beams depicted in FIG. 2 are always frequency-locked.

Referring now to FIG. 2, a schematic layout of a system 100 is illustrated according to various embodiments of the present disclosure. System 100 is configured to implement certain methods of the present disclosure. System 100 includes various optical sensing components and various electronic instrumentation. A coupling beam 102 (illustrated in blue) and a dressing beam 104 (illustrated in red) are laser beams which co-propagate and overlap in a vapor cell 108 (e.g., an alkali vapor cell) containing an element (e.g., atomic rubidium) with a probe beam 106 (illustrated in orange), which is illustrated entering from the opposite direction. All beams are coaxially aligned and overlap in the vapor cell 108. The coupling beam 102 frequency sidebands are generated by an electro-optic modulator (EOM) 110, and then transferred to the probe beam 106 via the 6 WM process when all lasers are on (or near) resonance. The probe carrier frequency, along with any transferred sideband content, is focused (e.g., using a focusing lens 112) onto a fast photodiode (PD) 114 to generate a beat note 116 between the probe carrier and acquired sidebands. The beat note 116 is bandpass-filtered (e.g., using a bandpass filter 118) and amplified (e.g., using a RF amplifier 120) before demodulation (e.g., using a demodulator 122) in a double-balanced mixer. Demodulator 122 is configured to measure the instantaneous phase of the radiofrequency beating (i.e., the beat note) of the optical probe frequency, ωₚ, with its acquired sidebands, ωₚ+ω_{RF} and ωₚ-ω_{RF}. The mixer output voltage is proportional to the phase of the beat note, revealing the characteristic phase-reversal signal associated with MTS.

The schematic layout of FIG. 2 describes a system (or apparatus) 100 which can be used to study three-color excitation in a second vapor cell, also containing natural isotopic mixture of an alkali element (e.g., atomic rubidium). Sidebands at ωc+ω_{RF} can be generated on the coupling beam 102 by passing it through an electrooptic modulator 110 (e.g., EOM-New Focus 4002) driven at frequency ω_{RF}. The coupling beam 102 and dressing beam 104 are combined with a dichroic mirror (DM) 126 before entering vapor cell 108, while the probe beam 106 propagates in the opposite direction (e.g., where probe beam 106 passes through dichroic mirror 130 while coupling beam 102 and dressing beam 104 are reflected to a beam stop). All beams are initially overlapped using a pair of irises on either side of the vapor cell; minor beam-steering adjustments are made as needed to maximize signal strength (e.g., using dichroic mirrors 128 and 130). In certain embodiments, vapor cell 108 is a 7.5-cm long rubidium vapor cell. Vapor cell 108 can be heated to approximately 10° C. above room temperature (e.g., or to a temperature sufficient to provide gaseous alkali atoms).

The probe beam 106 is separated from the coupling beam 102 and dressing beam 104 with a dichroic mirror (DM) 128. In certain embodiments (not illustrated), probe beam 106 can be sent to a slow photodiode (e.g., SPD-Thorlabs DET110) to monitor the EIT signal. In FIG. 2, probe beam 106 is illustrated being provided to focusing lens 112 and then to fast photodiode 114 (e.g., an amplified photodiode, FPD-Electro-Optics Technology ET-2030A, etc.) to detect the beat note 116 between the probe carrier frequency and sidebands acquired in the vapor cell 108 due to frequency mixing. The fast photodiode 114 output is amplified using RF amplifier 120 (e.g., A-Minicircuits ZFL-500LN and/or Stanford Research Systems 445A) and optionally filtered with bandpass filter 118, such as a non-commercial high-Q bandpass filter (e.g., 10.7 MHz center, 6 kHz FWHM) before distribution to a phase detector (e.g., DBM-Minicircuits ZRPD-1+) and vector voltmeter (e.g., VV-Hewlett-Packard HP8405A). The EOM drive signal and phase-programmable reference signals at frequency ω_{RF} can be supplied by synchronized direct-digital synthesis signal generators (e.g., DDS-Rigol DG822). When used to frequency-stabilize the coupling laser, this signal is conditioned by a servo controller 132 (e.g., LPF-Newport LB1005) that provides frequency filtering and attenuation. Finally, a vector voltmeter can be used to measure the beat note amplitude, providing a phase-independent reference feature for aligning successive laser frequency scans that can exhibit frequency drift.

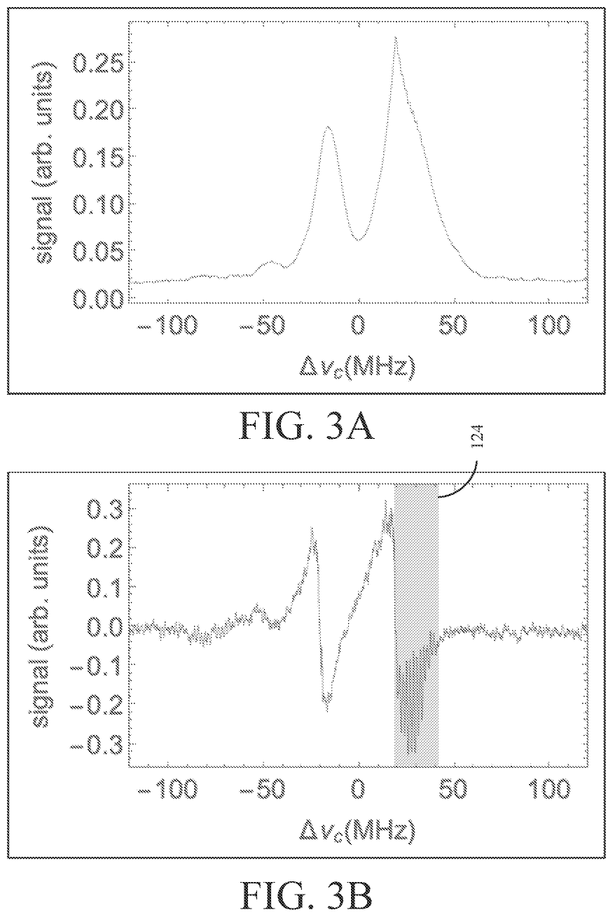

Referring now to FIGS. 3A-3B, an MTS response is illustrated. Referring specifically to FIG. 3B, the MTS response is illustrated when a 500 Hz, 640 mV/m electric field is applied to atoms in the vapor cell (e.g., vapor cell 108). Here the coupling laser is scanned across the 60F_{5/2} resonance. Shaded area 124 highlights the portion of the MTS spectrum that is sensitive to low-frequency electric fields. For comparison, FIG. 3A illustrates a simultaneously recorded EIT signal generated by the same laser beams in the same cell. As illustrated, the size of the EIT response to the electric field is noticeably smaller. To quantify the MTS detection sensitivity at low frequencies, it is necessary to account for the Faraday screening of an electric field that occurs within vapor cells (e.g., alkali vapor cells).

In certain embodiments, rubidium is used in the vapor cell. Near room temperature, rubidium is a solid metal, so the interior wall (e.g., made of Pyrex or other suitable materials) of the vapor cell containing an alkali vapor is unavoidably coated with a layer (e.g., a microscopic layer) of conductive, metallic rubidium. A test electric field (e.g., applied by metal plates) outside the vapor cell is thus attenuated in the vapor cell interior, where the atoms and laser beams interact, due to a Faraday shielding effect. This shielding effect can be measured using EIT measurements and/or finite-element simulations of the setup geometry to estimate the shielding effect. Thus, in determining an electromagnetic field using a system of the present disclosure, the described shielding effect can be accounted for.

An experimental method (i.e., without simulation) to measure the frequency-dependent Faraday shielding in a vapor cell is described herein. For example, in the same vapor cell that is used for MTS electrometry, the laser beam configuration can be left unchanged except that the coupling laser frequency is tuned to excite the 33P_{1/2} or 36P_{1/2} state, and the beam powers are adjusted to optimize EIT signal. The atomic polarizabilities of Rydberg P-states can be calculated to better than 1%, facilitating the prediction of the time-averaged Stark shift caused by the low-frequency electric field sampled by the atoms.

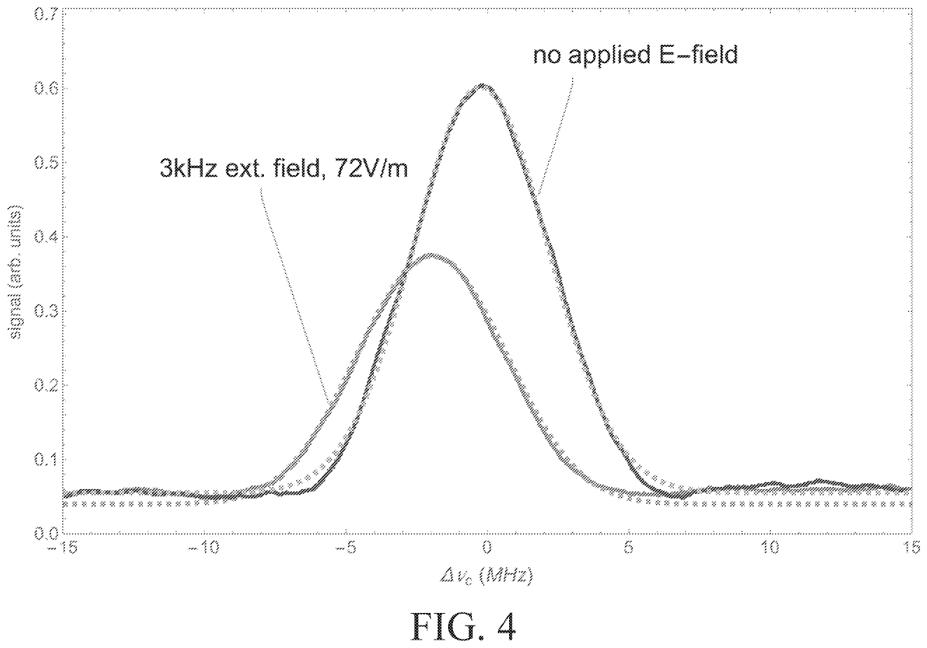

Referring now to FIG. 4, signals for calibrating frequency-dependent Faraday shielding inside the rubidium vapor cell are illustrated. EIT signals are illustrated from excitation to the 33P_{1/2} state, without applying an electric field (illustrated in a solid blue line) and with a 3 kHz, 72V/m external electric field applied (illustrated in a solid red line) via large, parallel metallic plates outside the vapor cell. The signal without an electric field is qualitatively well-described by a Gaussian (illustrated in a dashed green line). Although the wings of the signal deviate somewhat from the fit, the peak and FWHM are consistently well matched to the fit. Using this fitted Gaussian as a basis function, the time average of the expected Stark-shifted response due to the applied oscillating E-field is calculated (illustrated in a dashed orange line). Apart from a multiplicative amplitude scaling factor to account for slow drift in signal strength (no independent vertical offset is employed), the only parameter used to match the calculated, time-averaged response to the measured signal, with electric field present, is a transmission factor for that field, 0<η<1. This represents the fraction of the external electric field amplitude that is sampled by the atoms in the interior of the alkali-metal coated, fused-silica (Pyrex) cell.

Using such a measurement (e.g., as described in connection with FIG. 4), the overall frequency-dependent Faraday screening for a vapor cell can be characterized using the following procedure. First, the optimal Gaussian basis function without applied E-field is generated by averaging multiple Gaussian fits. Second, the scale of the coupling laser frequency scan is calibrated with a Michelson interferometer with 8.7 MHz fringe spacing. Third, the zero for the frequency scale of the coupling laser scan is generated from the simultaneous EIT signal produced in a second, separate vapor cell encased in a metal shield to zero the electric field—all beams are derived from the same lasers used in the main cell. Fourth, multiple measurements are made between 0-100 kHz, using excitation to both the 33P_{1/2} and 36P_{1/2} states as a systematic check.

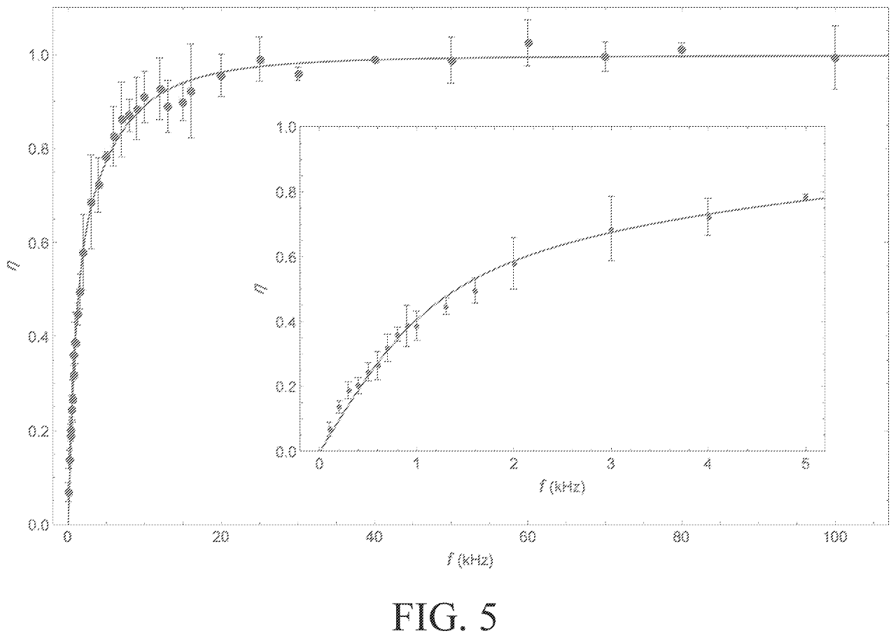

Referring now to FIG. 5 the frequency-dependent variation of the transmission data in a main vapor cell, along with statistical error bars, is illustrated (with an inset figure of the 0-5 KHz frequency range). The fit to the data is based on the expected high-pass frequency filtering behavior due to a metallic rubidium layer. Given the two-fold geometrical symmetry of a cylindrical vapor cell between parallel field plates (spaced at the cylinder diameter), the following linear combination is used (with fit parameters f₁ and f₂ representing independent characteristic cutoff frequencies arising from the vapor cell geometry and A determining the relative weight of each cutoff behavior):

$$η ( f ) = A \frac{f}{\sqrt{{f}^{2} + {f}_{1}^{2}}} + ( 1 - A ) \frac{f}{\sqrt{{f}^{2} + {f}_{2}^{2}}}$$

In FIG. 5, the fit is calculated where f₁=1.3 kH7, f₂=9.0 kHz, and A=0.60. This function calibrates the frequency-dependent electric field transmission to ±2% at the 95%-confidence level. The internal electric field can be calculated from the measured voltage applied to, and spacing of, the external field plates that generate the electric field.

Applying a one (1) kHz internal electric field with amplitude

$$114 \frac{mV}{m} / \sqrt{Hz}$$

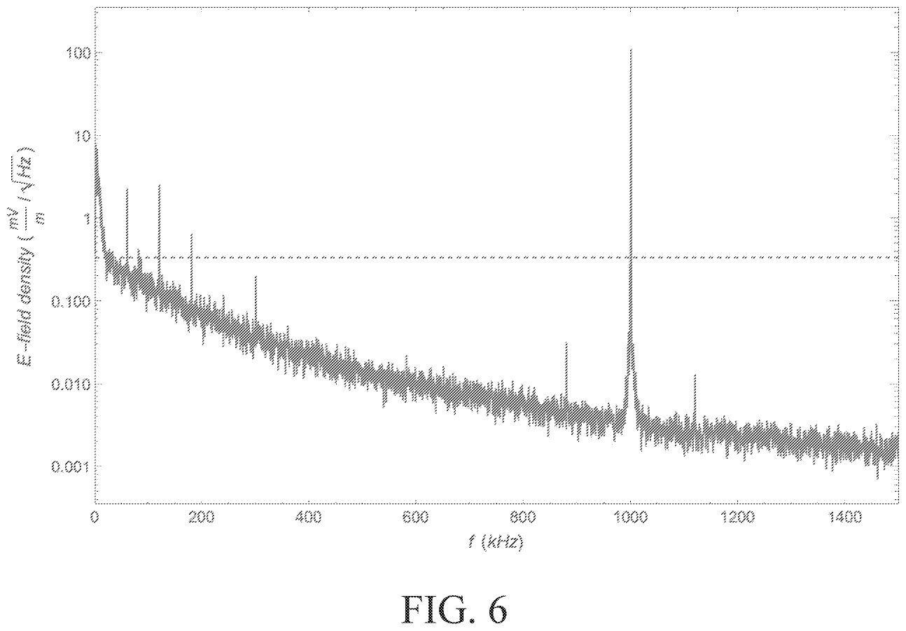

as a known reference signal, the MTS electrometer output yields the spectrum illustrated in FIG. 6.

FIG. 6 illustrates a fast Fourier transform (FFT) of the signal integrated over 50 s. Here, the coupling laser is tuned to the range of maximal ULF sensitivity with excitation to the 60F5/2 Rydberg state. At one (1) kHz, the noise floor at

$$0.0034 \frac{mV}{m} / \sqrt{Hz}$$

is over 4 orders of magnitude lower than the reference signal. For comparison, the corresponding noise floor reported in a recent EIT-based electrometer measurement is shown by the dashed red line at

$$0.34 \frac{mV}{m} / \sqrt{Hz} .$$

The measurement (i.e., the dashed red line) used a special monocrystalline sapphire vapor cell to reduce the adsorption of metallic rubidium (and thus Faraday screening), as well as a frequency-mixing, or “heterodyning” technique. The MTS method of the present disclosure should be compatible with (and/or enhanced by) the use of a similar specialized vapor cell. The reduced Faraday screening would result in almost complete transmission of the external field at one (1) kHz.

Separate from the Faraday screening effect, the MTS process of the present disclosure can facilitate heterodyning in the MTS spectrum. While the applied one (1) kHz oscillating potential has no measurable sidebands, clear sidebands at one (1) kHz±120 Hz are visible in the received signal spectrum of FIG. 6. This can be due to atomic mixing of the one (1) kHz reference signal with an ambient 120 Hz electric field, which is also directly visible in the MTS spectrum as the second strongest AC component. It is contemplated that certain embodiments of the present disclosure can deliberately exploit such an effect to measure even smaller signals in the sub-kHz frequency regime.

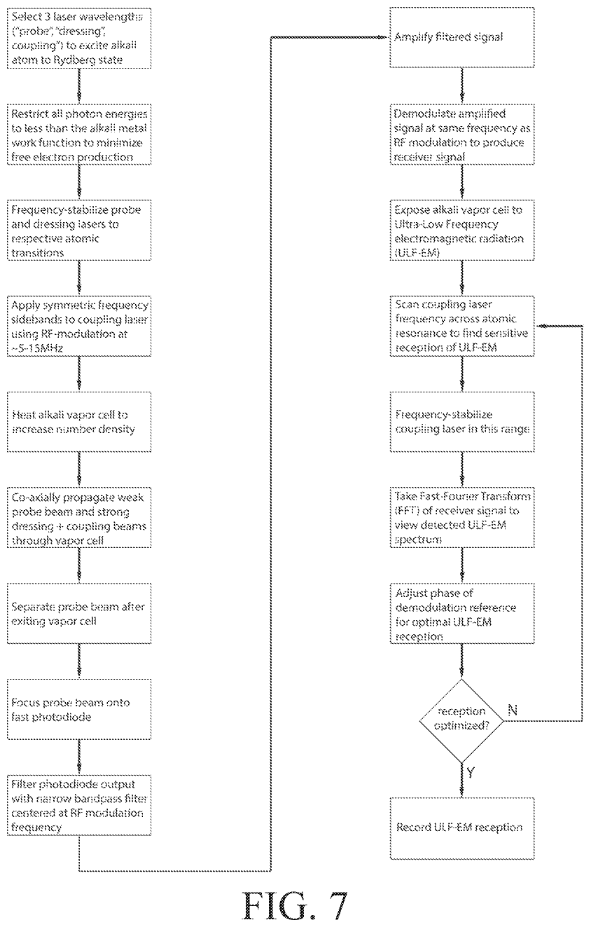

FIG. 7 illustrates a flow chart for implementing a ULF receiver using MTS electrometry, in accordance with certain exemplary embodiments of the present disclosure. The flow chart illustrates a general method for detecting carrier signals in the ULF frequency range. Various methods for encoding and decoding information, through amplitude, frequency, or phase, are contemplated using the system (and/or apparatus) of the present disclosure. The method of certain exemplary embodiments of the present disclosure are compatible with various alkali atoms (e.g., lithium, sodium, potassium, rubidium, cesium, etc.), each with multiple available excitation wavelength schemes. The specific laser wavelengths described herein are exemplary in nature. Specific laser wavelengths described herein can be described in connection with a solid-state laser being employed. However, the disclosure is not so limited and various other lasers and frequencies may be employed. For example, a system (and/or apparatus) design using only diode-and/or fiber-lasers is contemplated. Such embodiments enable compact, stable, high-performance, and/or relatively low-cost construction of various embodiments. In certain embodiments, selecting photon energies below the alkali atom work function can minimize free electrons inside the vapor cell, facilitating clear interpretation of the spectrum.

In certain embodiments of the present disclosure, the operating conditions of methods and systems for detection of electromagnetic fields can be described as follows.

Vapor Cell Parameters

| | |
|---|---|
| Temperature | ~30° C. |
| Beam Propagation | Probe beam propagation direction opposite |
| | to dressing/coupling beam propagation |

Beam Parameters

| | 780-nm laser beam | | 1529-nm laser beam | | ~700-nm laser beam | |
|---|---|---|---|---|---|---|
| Beam Diameter | 0.5-3 | mm | 1-3 | mm | 0.5-3 | mm |
| Power | 0.2-2 | mW | 1-100 | mW | 100-1000 | mW |

| | | | |
|---|---|---|---|
| Bandwidth | ~1 MHz | ~1.5 MHz, stabilized | 100 kHz, stabilized |
| | stabilized to atomic | to atomic resonance | to atomic resonance |
| | resonance using 1- | using 2-color MTS | using 3-color MTS |
| | color MTS technique | technique | technique |
| Polarization | Linear | Linear | Linear |

Sideband Parameters

| | |
|---|---|
| Coupling Beam Sidebands | Produced with an electro-optic modulator |
| | (EOM) driven at 5-15 MHz |
| Sideband Strength | 5-10% relative to carrier power |

Beat Note Phase Measurement Parameters

| | |
|---|---|
| Photodiode Responsivity | 0.5 A/W at 780 nm wavelength |
| Signal Amplification Before Phase | 50-70 dB |
| Measurement | |
| Passive Phase Detector Sensitivity | 2.9 V/rad |

Provided herein is another method for detecting electric field (E-field) in the ranges of extremely low frequency (ELF: 3-30 Hz), super low frequency (SLF: 30-300 Hz), and ultra low frequency (ULF: 0.3-3 kHz). This “E-field-modulation” (EFM) technique uses a similar system as other systems described herein (e.g., system 100 of FIG. 2). The differences between system 100 and 200 can result in important differences in the production of the desired signal.

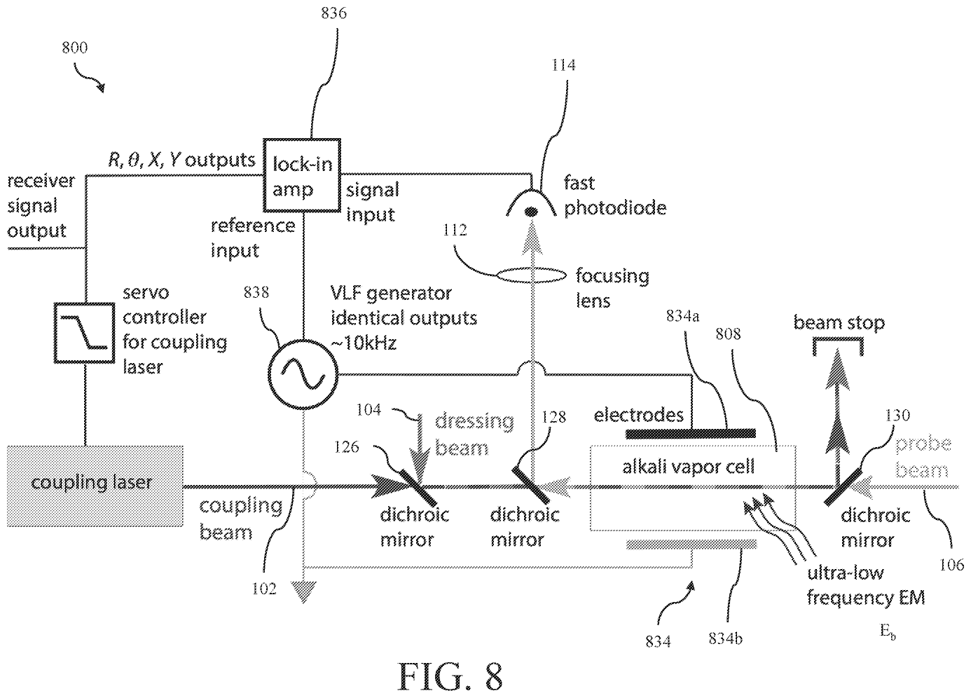

In FIG. 8, system 800 is provided. System 800 is substantially the same as system 100, where like reference numerals denote like elements. Three laser fields (i.e., probe beam 106, dressing beam 104, and coupling beam 102) are applied to atomic rubidium vapor in a transparent cell as described in connection with FIG. 2. Probe, dressing, and coupling laser beams are nominally co-linear and overlap near the center of the cell. Each laser field is linearly polarized with its polarization vector aligned approximately in the direction of the low-frequency and/or DC E-fields. FIG. 8 is a schematic diagram of the optical and electronic paths used in this experiment. The probe and dressing laser beams are frequency-stabilized to the same resonances of atomic rubidium described in the modulation-transfer method. For the field-modulation technique, however, the coupling beam is tuned to excite an nF_{7/2} resonance (n˜60) of Rb and frequency sidebands are not used. Instead, a modulation electric field at frequency Vₘ=ωₘ/(2π)˜10 kHz is applied to the atomic vapor via electrodes 834 (e.g., including upper electrode 834a and lower electrode 834b); the variables v and w denote frequency and angular frequency, respectively. Interaction of the laser beams and modulation field is mediated by the atoms, resulting in the probe beam acquiring new frequency components offset from vₚ by ±vₘ. Because vₘ is about the same size as the linewidth of the transition to the Rydberg state, the entire nonlinear mixing process is nearly resonant. The enhanced signal strength of the field-modulation method may be a direct result of this condition.

After traversing the vapor cell 808, the probe beam (traveling in the opposite direction of the dressing and coupling beams) is focused onto a fast photodiode 114. The signal from the fast photodiode is demodulated at vₘ by a lock-in amplifier (LIA) 836 that outputs standard in-phase (X), quadrature (Y), magnitude (R), and phase (θ) signals. These outputs, collectively labeled “receiver signal output” in FIG. 8, are recorded with an oscilloscope as the coupling laser beam frequency is swept across an nF₇₂ atomic resonance (ω₀).

Two separate cases are described below. First, a specialized vapor cell with internal field plates as electrodes (within the vapor cell containing atomic rubidium) is used to characterize the sensitivity of the effect, without having to account for the Faraday screening effect. Second, a standard vapor cell (without internal field plates) is configured with outside electrodes to realize a sensor capable of detecting E-fields of external origin.

### Characterization of Effect

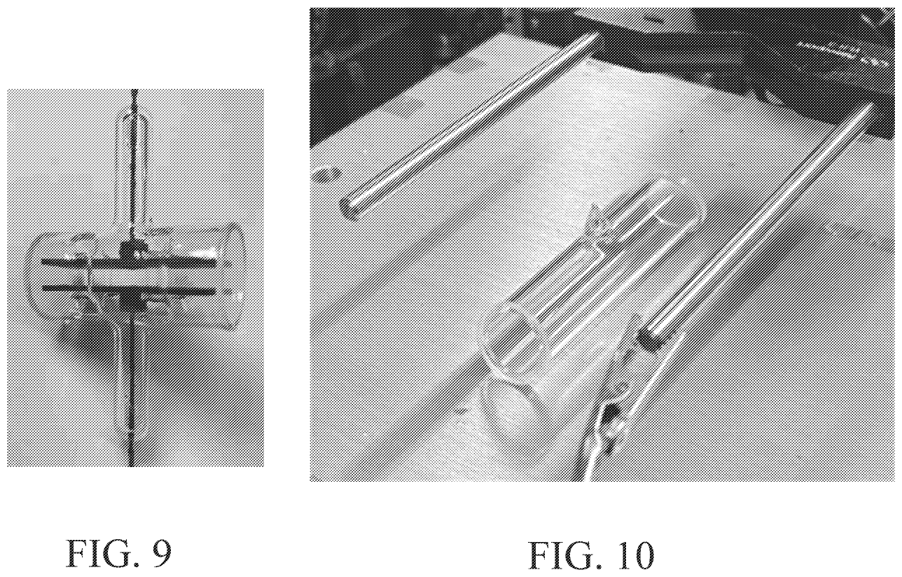

FIG. 9 illustrates a photo of the specialized rubidium vapor cell with internal electrodes (e.g., manufactured by Precision Glassblowing (Centennial, CO)). Two parallel plates made of non-magnetic stainless steel are positioned within the cell at a separation of d=0.5 cm. Electrically conducting vacuum feedthroughs allow the application of independent voltages to the two electrodes. To demonstrate the sensitivity of the field-modulation method to DC or low-frequency electric field, a variable bias voltage, V_{b}, is applied to the bottom plate, while the top plate is modulated with a sinusoidal voltage waveform at frequency vₘ=11 kHz and amplitude vₘ=17 mV. Note that although the lower electrode 234b in FIG. 8 is schematically depicted outside the cell and held at electrical ground, for this section it represents the internal bottom field plate at bias voltage, V_{b}, which is either constant in time or slowly varying compared to the modulation frequency, vₘ. In the parallel-plate approximation the vertical electric field at the center of the cell can thus be written as (VₘCos[2πvₘt]−Vₚ)/d, where t is the time variable (with an arbitrary phase offset set to zero). Atoms (e.g., Rb) at the cell center sample the equivalent of a vertically polarized modulation electric field, Eₘ=VₘCos[2Tπvₘt]/d, and a parallel bias electric field of magnitude E_{b}=V_{b}/d. A goal of the field modulation technique is to detect E_{b}.

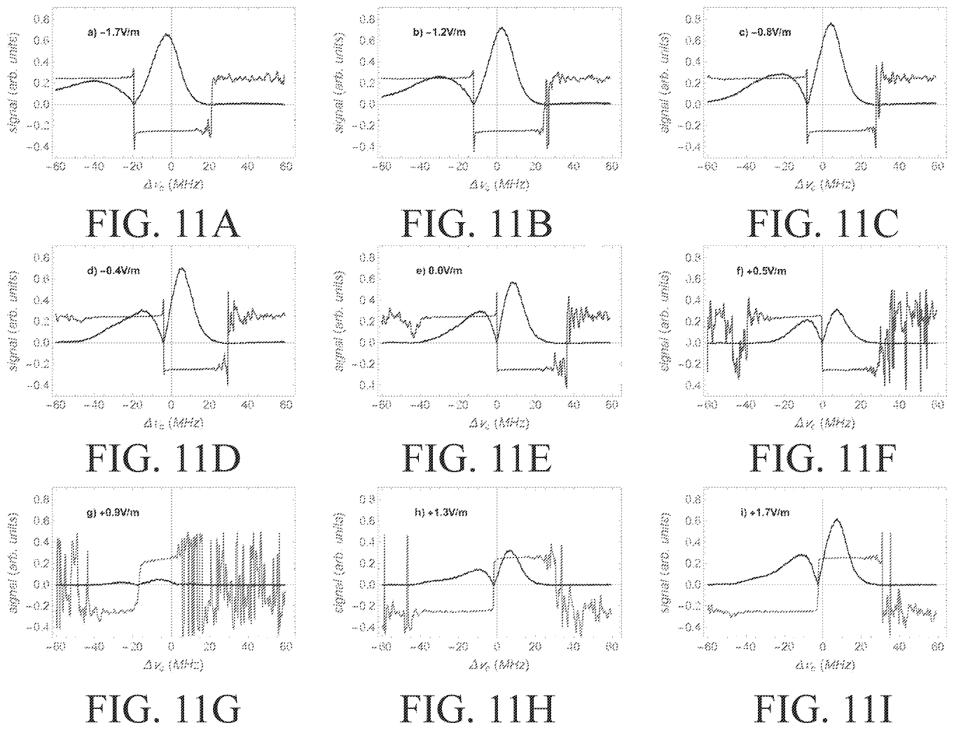

Under these conditions, the receiver signal output is recorded while the coupling laser detuning from the time-averaged 62F_{7/2} atomic resonance, Δv_{c}=(ω_{c}−ω₀)/(2π), is scanned. FIGS. 11A-1I shows plots of R (darker line), and θ (lighter line) vs. Δv_{c}. The constant value of E_{b} is denoted in each panel, ranging from −1.7V/m in FIG. 11A to +1.7V/m in FIG. 11I. FIG. 11E shows the spectrum when the bottom plate is grounded, i.e., the bias electric field is zero; the coupling laser detuning is defined to be zero at the sharp cusp in R in FIG. 11E.

LIA 236 demodulates the photodiode signal at vₘ, picking out only that frequency component and giving its magnitude, R, and phase, θ, relative to the reference signal. The plots of R in FIG. 11 show that the magnitude responds to the bias field with a change in size, as well as a frequency shift. The θ signal exhibits a phase jump that always coincides with the sharp cusp in R; notably, this feature has opposite sign for FIGS. 11A-11F compared to FIGS. 11G-11I. None of these behaviors is symmetric with respect to the bias field (same signals for ±E_{b}), indicating they cannot be solely a consequence of the Stark shift, which is proportional to the square of the electric field:

$$Ω ( t ) = - \frac{1}{2} α {E ( t )}^{2} .$$

Here, the polarizability of the 62F_{7/2} state is given by α=94 MHz/(V/cm)². Instead, both signals respond to the size and sign of the applied bias field, showing that at least one additional mechanism is needed to explain the observed variation in R and θ as the field is varied.

Notwithstanding the ultimate cause of the asymmetric response, the bias field causes a measurable change in the LIA output. The receiver signal output is characterized herein for the purposes of sensitively detecting small values of E_{b} in the ELF, ULF, and SLF ranges.

Certain experiments described herein demonstrate the response to an SLF bias field. Accordingly, the constant voltage on the lower internal field plate was replaced with a 100 Hz sinusoidal voltage waveform; this sets up an oscillating bias electric field with amplitude E_{b}=0.72V/m that is sampled by the atoms at the cell center. FIG. 12 shows the response of R and θ as the coupling laser frequency is scanned. While both signals are affected by the oscillating bias voltage, the R signal near −5 MHz clearly exhibits a strong response.

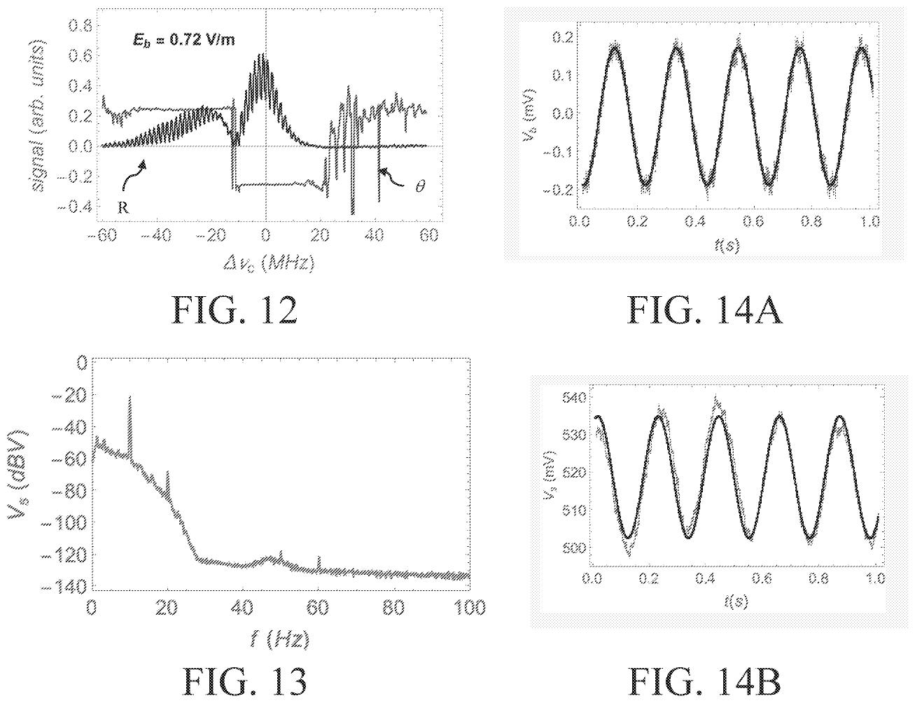

Lowering the frequency to the ELF range and switching to the X output of the LIA, all parameters (including modulation amplitude, phase of the reference signal, LIA time constant) were optimized to maximize the size and signal-to-noise ratio of the response. The coupling laser was then set at the detuning that produces the largest amplitude response. FIG. 13 illustrates a Fast Fourier Transform (FFT) of the recorded X signal, averaged over 50 s while a 10 Hz bias field with amplitude E_{b}=0.20V/m was applied. The signal peak sits almost four orders of magnitude above the noise level for this low-frequency bias field.

Further lowering the frequency to 4.7 Hz, a bias voltage was applied to produce a field amplitude of E_{b}=0.03V/m. FIGS. 14A-14B illustrate the X response in the time domain. FIG. 14A illustrates the driving waveform (light trace), with a fit to a sinusoid (dark trace); the bottom panel shows the X output signal (light trace), fit to a different sinusoid (dark trace). Although a lower-frequency component can be discerned in the output signal, either due to electronic noise or actual electric field, the measured output has a recognizable linear response. From the curve fit parameters, an intrinsic sensitivity (measured signal amplitude per applied electric field amplitude) of 0.44 V/(V/m) can be inferred. This represents the ideal sensitivity to an external field oscillating at 4.7 Hz, without having to account for Faraday screening or dielectric effects of vapor cell walls.

### Open Structure for Modulation Electrodes: Sensor Application

To employ the field modulation response characterized in the previous section as an environmental sensor, the atoms must be situated in a mostly conductor-free environment so that fields of external origin are efficiently transmitted to the cell center. This precludes having internal field plates such as those in the specialized vapor cell described above. Furthermore, a layer of metallic rubidium on the inner cell wall is unavoidable and causes Faraday screening of low frequencies, though the effect can be mitigated by making the vapor cell out of materials that minimize the conductive layer, which will be briefly discussed later in this section. Although the sensitivity to fields in the lower frequency ranges will be diminished, vapor cells made of common materials (e.g., fused silica, borosilicate glass, etc.) still allow for efficient E-field transmission near 10 kHz, allowing a modulation field within the cell to be applied to the atoms via external electrodes.

FIG. 10 shows a photo of a test setup described herein with a standard (no internal electrodes) fused silica vapor cell placed in an open electrode structure. The cell rests on an aluminum plate that is electrically grounded and functions as one electrode for the application of a modulation field. Two electrically connected rods (parallel and equidistant to the vapor cell cylinder axis) are placed 5 cm above the bottom plate. Following the formalism established above, a voltage waveform is applied to the rods to create a modulation electric field, Eₘ, within the cell. In the experiments described herein, the coupling laser was tuned to the 60F_{7/2} atomic resonance and a vₘ=11 kHz was used (Vₘ=230 mV). Knowledge of the precise value of Eₘ is not critical to the method. Based on the electrode geometry, the modulation field at the cell center is approximately vertically oriented and its amplitude can be controlled with Vₘ. To apply a test bias field, a large square metallic plate (not shown) was situated at a distance s=13 cm above the bottom plate. V_{b} was applied to the top plate, creating a field approximately given by E_{b}=V_{b}/s. Aside from these changes, the setup is identical to the previously described apparatus.

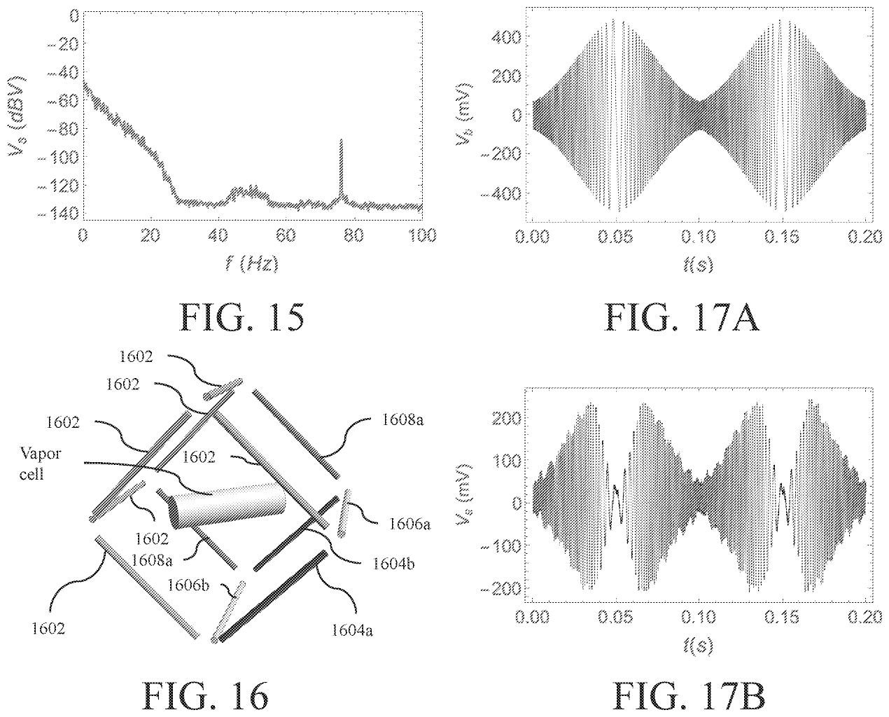

With this setup, FIG. 15 illustrates an FFT of the optimized X-output of the LIA when a 76 Hz bias field with amplitude E_{b}=3.8V/m is applied externally. The actual internal field at this frequency is not know because the Faraday shielding has not been measured for this particular vapor cell. If one assumes a typical value for the Faraday-shielding cutoff frequency, f_{3dB}=10 kHz, the transmission factor would be 0.0076, implying a bias field amplitude of about 0.029V/m within the cell. The peak signal height at 76 Hz is about four orders of magnitude above the noise floor at that frequency.

A structure with additional electrodes should enable the application of three mutually perpendicular modulation fields, each of which can oscillate at a different frequency, allowing independent demodulation at those distinct frequencies to interrogate the separate polarization components of an arbitrarily polarized external bias field. FIG. 16 illustrates a schematic diagram of such an example, with a vapor cell shown at the center. The scale of the electrode structure, relative to the cell size, will likely be larger than depicted. Six rods 1602 comprising the left half of the cube would be connected to electrical ground, while each remaining pair of parallel rods (i.e., 1604a and 1604b; 1606a and 1606b; and 1608a and 1608b) would be driven at a unique modulation frequency, allowing independent demodulation of the photodiode signal at each unique frequency. Because each frequency is associated with a single axis (orthogonal to the other two), simultaneous measurement of all three bias field polarization components can be implemented using the field modulation method. Laser beams would enter and exit the system at the vertices of the cube shape and pass through the vapor cell along its cylinder axis, in the usual way.

Another useful attribute of the field modulation method provides sensitivity to time-varying bias fields. In an experiment described herein, a standard vapor cell was placed between large external parallel plates at 2.5 cm spacing, with the bias voltage applied to the bottom plate and the modulation voltage to the top plate. A bias voltage was a sinusoidal waveform that varies in frequency between 0.1-1.9 kHz while it is also amplitude modulated with a depth of 85%, as illustrated in FIG. 17A. The frequency of the AM and FM pattern is 10 Hz. FIG. 17B illustrates the X signal from the LIA, which was responsive to the FM and AM character of the bias field. The effect of Faraday screening was evident in the received signal, as the amplitude of Vₛ is smallest during the low-frequency intervals of the waveform (at times 0.05 s and 0.15 s), even though V_{b} is simultaneously at maximum amplitude.

The intrinsic low-frequency sensitivity of the field modulation method could be fully exploited by incorporating a vapor cell that mitigates the Faraday effect. Although all demonstrations described in this document use standard vapor cells made of either fused silica or borosilicate glass, it has long been known that monocrystalline sapphire results in less conductive surfaces when alkali metals are adsorbed on it. This makes it an excellent material for fashioning vapor cells intended for low frequency electrometry; it has been shown that a vapor cell made of monocrystalline sapphire has surface resistance orders of magnitude higher than that of a fused silica cell, and thus exhibits far weaker Faraday screening at low frequencies. The ideal realization of a low-frequency sensor based on the field-modulation approach would combine the electrode structure of FIG. 16 with a monocrystalline sapphire vapor cell; the concomitant improvement in sensitivity is expected to be two or three orders of magnitude.

### Sensitivity to Light

It has been shown that EIT-based electrometry in vapor cells can be affected by sources of light in addition to the laser beams used to probe atomic Rydberg states. This phenomenon is explained by the work function of metallic alkali metals, i.e. the minimum photon energy needed to liberate a single electron from the metal. For Rb, the work function is 2.26 eV, so photons with wavelength 549 nm or lower can liberate free charges within the vapor cell by knocking out electrons from the rubidium layer on the inner cell wall.

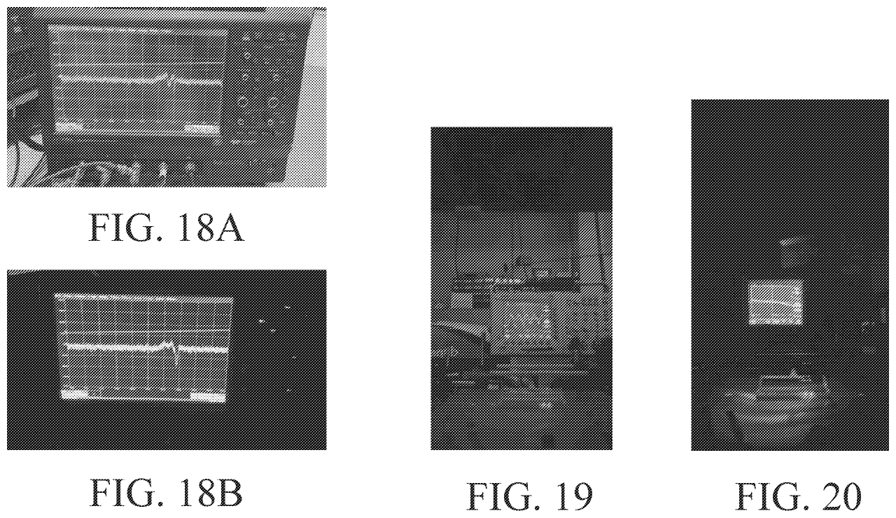

Fundamentally, the additional electric field of a free charge distribution within the cell volume will Stark-shift the Rydberg level being excited by the coupling laser, changing the resonance feature. Room lights being turned on and off can have a significant effect on the size and shape of the resonance (see FIG. 18). Maximal control over the sensor environment requires that the sensing vapor cell be placed in an enclosure (non-conducting) that blocks all light except for the laser beams. This is a straightforward measure to implement. It is also possible, however, that a controlled light source might be used to enhance the overall sensitivity of the field-modulation technique to the bias field being detected. This is a possibility that needs further exploration.

### Sub-ELF Detection

The open-electrode configuration also exhibits sensitivity to E-fields at frequencies below 3 Hz, a range without a common designation. FIG. 19 illustrates a setup with the modulation field applied using the plate and rods and all lasers traversing the cell. Instead of applying the bias field using an electrode, a transparent plastic ruler is moved back and forth above the cell. To make the signal stronger, the ruler is given static charge by rubbing it with a piece of foam. The charged ruler is then wiggled above the vapor cell-about once per second-to show the instrument response, which is displayed as the X-output of the LIA on the oscilloscope trace. The room lights are deliberately dimmed to avoid creating uncontrolled free charges in the cell and a transparent ruler is used, so it is unlikely that the motion of the ruler creates a temporal variation in the free-electron distribution within the cell.

To verify this, a similar demonstration is illustrated in FIG. 20, which is taken with the room lights off and the charged ruler waved back and forth more slowly above the vapor cell. The repetition rate is now approximately 0.5 Hz, but the change in bias field is strong enough so that each pass is clearly detected on the downward-sloping oscilloscope trace with good signal-to-noise ratio.

### Candidate Mechanism

The mechanism responsible for producing the receiver signal response must be consistent with several various observed behaviors, including: 1) strong signal amplitude at the modulation frequency, vₘ; 2) sensitivity to the sign of the bias field; and 3) linear response for small, low frequency fields. A candidate mechanism is 8-wave mixing (8 WM) involving the three laser fields at optical frequencies, the modulation field, and the bias field to be detected. These angular frequencies follow the hierarchy, ωₚ, ω_{d}, ω_{c}»ωₘ»ω_{b}, where ω=2πV relates the angular frequency to the frequency. Although such a high-order process is typically quite weak, in our case each laser is frequency-stabilized to the atomic resonance it is meant to drive, so the overall process can be strong. The term in the 8 WM generalized scalar product that corresponds to the optical transitions being driven near resonance results in electric polarization, [symbol] , that oscillates close to ωₚ. Co-linear polarization vectors were assumed for all fields. This term can be shown to have the following proportionality to [symbol] _{b}, the bias electric field: [symbol] ∝{Cos[(ωₚ+ωₘ)t]+Cos[(ωₚ−ωₘ)t]} [symbol] _{b}.

This is essentially the 8 WM field radiated along the direction of the original probe beam; when these two fields are focused onto the fast photodiode, the resulting lowest frequency term in the photodiode signal is proportional to E_{b}Cos[2πvₘt+ϕₘ], where ϕₘ is the overall phase of the response. Finally, the LIA demodulates the signal at vₘ to produce the outputs, X, Y, R, and θ.

A full theoretical treatment can be provided, which combines the putative 8 WM mechanism with the Stark effect, to comprehensively model of the behavior of the field-modulation experiment. Once certain scaling dependences have been predicted, experimental parameters can be varied to verify parametric relationships and validate the model.

Methods described herein include “Modulation Transfer Spectroscopy (MTS)” and “E-Field Modulation” (EFM); such methods are thought to rely on nonlinear wave mixing that is sensitive to low-frequency electric field in the vapor cell. In both cases a frequency modulation is transferred to the probe beam via atom-mediated interactions. In MTS the modulation (e.g., ˜10 MHz) is applied to the coupling beam, whereas in EFM the modulation (e.g., ˜10 kHz) is applied to the atoms as an electric field produced by electrodes. In both cases the optical frequencies contained in the probe beam after it traverses the vapor cell are mixed by focusing the beam onto a photodiode. The photodiode produces a resulting beat note that is subsequently demodulated at the modulation frequency to produce the receiver signal. This receiver signal shows sensitivity to low-frequency electric field sampled by the atoms in the vapor cell, including fields that can originate from external sources. The sensitive detection of such fields is the goal of both methods.

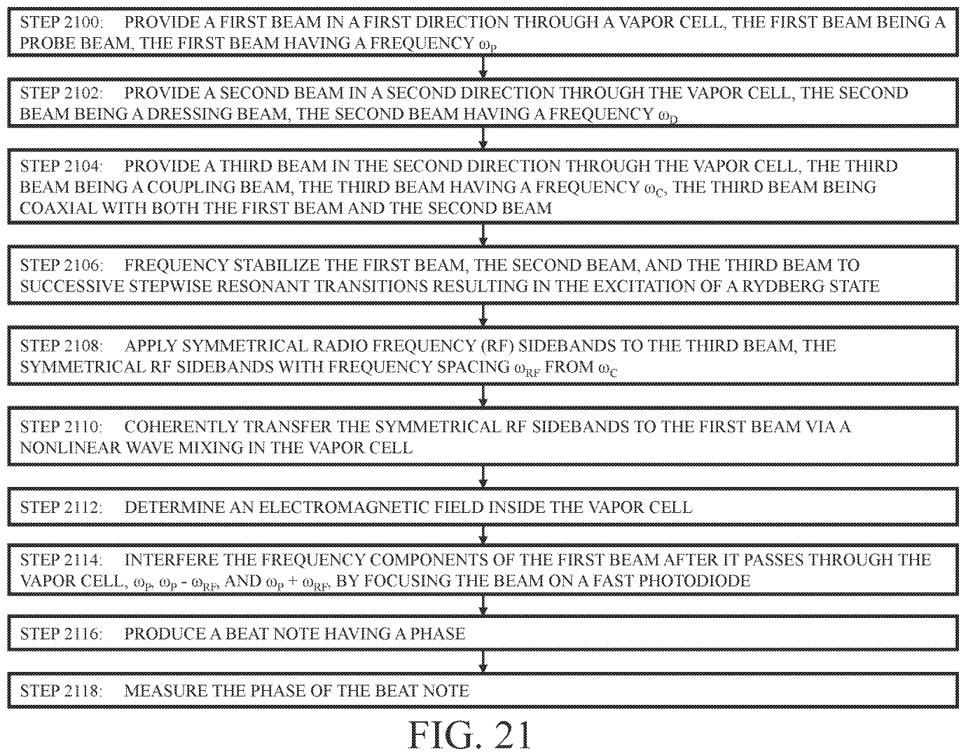

FIGS. 21-23 are flow diagrams in accordance with exemplary embodiments of the present invention. As is understood by those skilled in the art, certain steps included in the flow diagrams may be omitted; certain additional steps may be added; and the order of the steps may be altered from the order illustrated.

Referring specifically to FIG. 21, a method of detection of electromagnetic fields is illustrated. At Step 2100, a first beam is provided in a first direction through a vapor cell, the first beam being a probe beam, the first beam having a frequency ωₚ. At Step 2102, a second beam is provided in a second direction through the vapor cell, the second beam being a dressing beam, the second beam having a frequency ω_{d}. At Step 2104, a third beam is provided in the second direction through the vapor cell, the third beam being a coupling beam, the third beam having a frequency ω_{c}, the third beam being coaxial with both the first beam and the second beam. At Step 2106, the first beam, the second beam, and the third beam are frequency stabilized to successive stepwise resonant transitions resulting in the excitation of a Rydberg state. At Step 2108, symmetrical radio frequency (RF) sidebands are applied to the third beam, the symmetrical RF sidebands with frequency spacing ω_{RF} from ωc. At Step 2110, the symmetrical RF sidebands are coherently transferred to the first beam via a nonlinear wave mixing in the vapor cell. At Step 2112, an electromagnetic field is determined inside the vapor cell. Step 2112 can be the final step of this method. At Step 2114 (which can come before Step 2112), the frequency components of the first beam are interfered with after it passes through the vapor cell, ωp, ωₚ−ω_{RF}, and ωₚ+ω_{RF}, by focusing the beam on a fast photodiode. At Step 2116 (which can come before Step 2112), a beat note having a phase is produced. At Step 2118 (which can come before Step 2112), the phase of the beat note is measured.

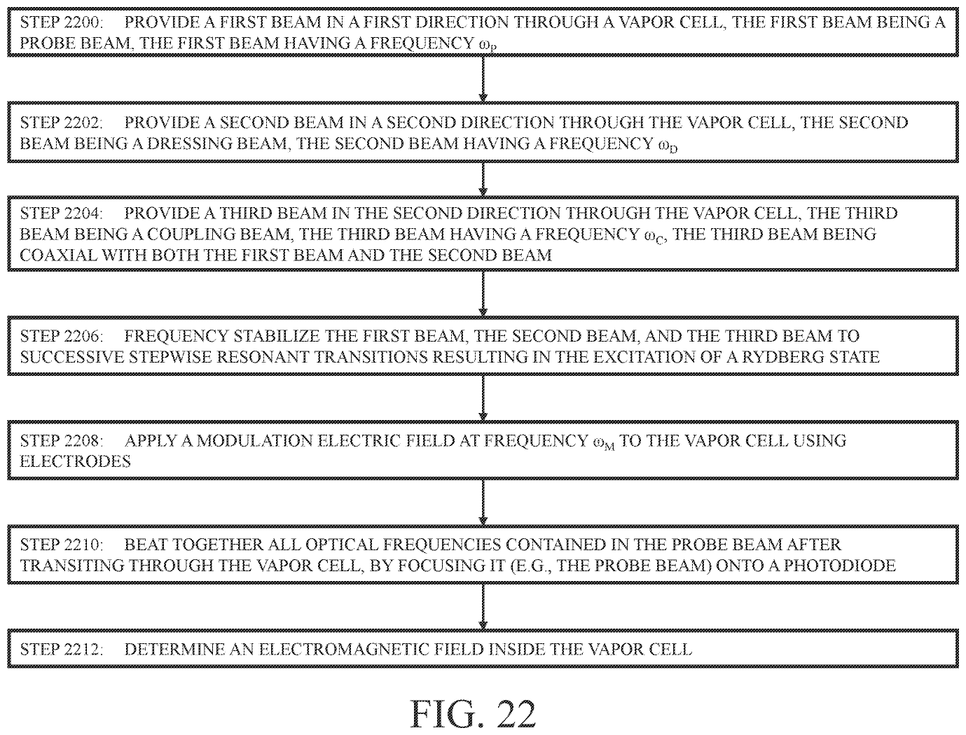

Referring specifically to FIG. 22, a method of detection of electromagnetic fields is illustrated. At Step 2200, a first beam is provided in a first direction through a vapor cell, the first beam being a probe beam, the first beam having a frequency ωₚ. At Step 2202, a second beam is provided in a second direction through the vapor cell, the second beam being a dressing beam, the second beam having a frequency ω_{d}. At Step 2204, a third beam is provided in the second direction through the vapor cell, the third beam being a coupling beam, the third beam having a frequency ω_{c}, the third beam being coaxial with both the first beam and the second beam. At Step 2206, the first beam, the second beam, and the third beam are frequency stabilized to successive stepwise resonant transitions resulting in the excitation of a Rydberg state. At Step 2208, a modulation electric field is applied at frequency ωₘ to the vapor cell using electrodes (e.g., see exemplary electrodes in FIGS. 8-10). At Step 2210, all optical frequencies contained in the probe beam are beat together after transiting through the vapor cell, by focusing it (e.g., the probe beam) onto a photodiode. At Step 2212, a photodiode signal at ωₘ is demodulated. At Step 2214, an electromagnetic field near (e.g., inside) the vapor cell is determined.

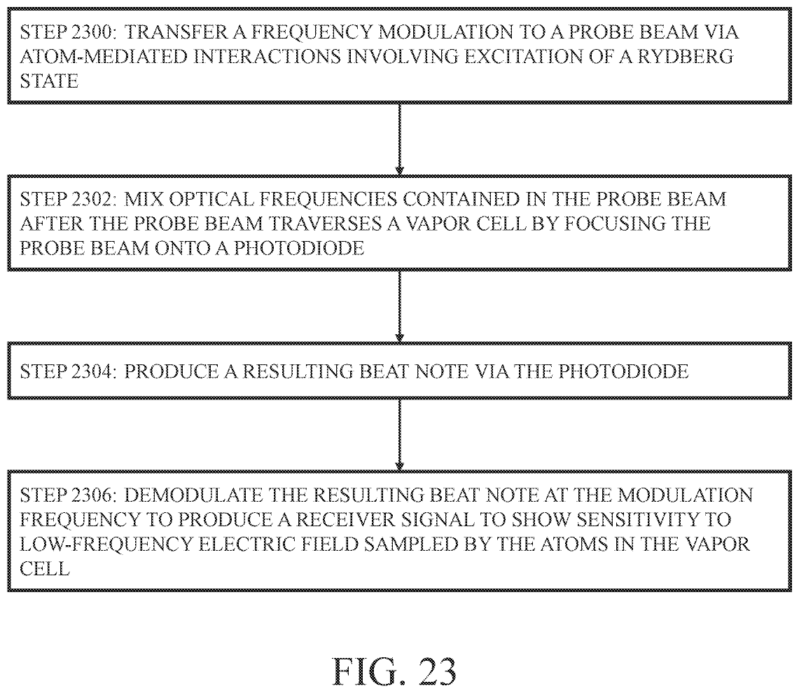

Referring specifically to FIG. 23, a method of detection of electromagnetic fields is illustrated. At Step 2300, a frequency modulation is transferred to a probe beam via atom-mediated interactions involving excitation of a Rydberg state. At Step 2302, optical frequencies contained in the probe beam are mixed after the probe beam traverses a vapor cell by focusing the probe beam onto a photodiode. At Step 2304, a resulting beat note is produced via the photodiode. At Step 2306, the resulting beat note is demodulated at the modulation frequency to produce a receiver signal to show sensitivity to low-frequency electric field sampled by the atoms in the vapor cell. In a final step, an electromagnetic field is determined inside the vapor cell.

### ENUMERATED EMBODIMENTS

The following enumerated embodiments are provided, the numbering of which is not to be construed as designating levels of importance.

Embodiment 1 provides a method of detection of electromagnetic fields, the method comprising the steps of: (a) providing a first beam in a first direction through a vapor cell, the first beam being a probe beam, the first beam having a frequency ωₚ; (b) providing a second beam in a second direction through the vapor cell, the second beam being a dressing beam, the second beam having a frequency ω_{d}; (c) providing a third beam in the second direction through the vapor cell, the third beam being a coupling beam, the third beam having a frequency ω_{c}, the third beam being coaxial with both the first beam and the second beam; (d) frequency stabilizing the first beam, the second beam, and the third beam to successive stepwise resonant transitions resulting in the excitation of a Rydberg state; (e) applying symmetrical radio frequency (RF) sidebands to the third beam, the symmetrical RF sidebands with frequency spacing ω_{RF} from ω_{c}; (f) coherently transferring the symmetrical RF sidebands to the first beam via a nonlinear wave mixing in the vapor cell; and (g) determining an electromagnetic field inside the vapor cell.

Embodiment 2 provides the method of embodiment 1, wherein, prior to step (g), the method further includes the steps of: (h) interfering the frequency components of the first beam after it passes through the vapor cell, ωₚ, ωₚ-ω_{RF}, and ωₚ+ω_{RF}, by focusing the beam on a fast photodiode; and (i) producing a beat note having a phase.

Embodiment 3 provides the method of any one of embodiments 1-2, wherein, prior to step (g), the method further includes the step of: (j) measuring the phase of the beat note.

Embodiment 4 provides the method of any one of embodiments 1-3, wherein the beat note is processed by a bandpass filter, an RF amplifier, and a demodulator.

Embodiment 5 provides the method of any one of embodiments 1-4, wherein the step of determining of step (g) includes recording a Modulation Transfer Spectroscopy (MTS) signal, the MTS signal being an output of the demodulator, and computing a Fast Fourier Transform of the MTS signal to visualize the frequency spectrum.

Embodiment 6 provides the method of any one of embodiments 1-5, wherein the step of determining of step (g) includes processing individual frequency components used as carriers for encoded information.

Embodiment 7 provides the method of any one of embodiments 1-6, wherein the step of determining of step (g) includes adjusting for a Faraday shielding effect from a conductive layer of an element within the vapor cell.

Embodiment 8 provides the method of any one of embodiments 1-7, wherein the vapor cell includes an element in a gaseous state, the element being alkali atoms.

Embodiment 9 provides the method of any one of embodiments 1-8, wherein the vapor cell includes an element in a gaseous state, the element being selected from the group consisting of: lithium, sodium, potassium, rubidium, and cesium.

Embodiment 10 provides the method of any one of embodiments 1-9, wherein the vapor cell includes an element in a gaseous state, the element being rubidium.

Embodiment 11 provides the method of any one of embodiments 1-10, wherein photons are coherently emitted at ωₚ-ω_{RF} and ωₚ+ω_{RF}.

Embodiment 12 provides the method of any one of embodiments 1-11, wherein the nonlinear wave mixing of step (f) is a 6-wave mixing (6 WM).

Embodiment 13 provides a system for detection of electromagnetic fields (e.g., configured to implement any of the methods of embodiments 1-12), the system including: a first laser source configured to provide a first beam, the first beam being a probe beam; a second laser source configured to provide a second beam, the second beam being a dressing beam; a third laser source configured to provide a third beam, the third beam being a coupling beam; a vapor cell, the vapor cell being configured to contain a gaseous alkali element; a first dichroic mirror configured to combine the second beam and the third beam; a second dichroic mirror configured to allow the first beam to pass through, while reflecting the second beam and the third beam; a third dichroic mirror configured to allow the second beam and the third beam to pass through while reflecting the first beam; and a plurality of signal processing components configured to analyze an electrical signal of the first beam.

Embodiment 14 provides the system of embodiment 13 wherein the plurality of signal processing components includes: a focusing lens for focusing the first beam; a fast photodiode for producing a beat note; a bandpass filter for filtering undesired frequencies of the electrical signal of the first beam; a RF amplifier for amplifying a portion of the electrical signal of the first beam; and a demodulator for measuring the instantaneous phase of the beat note.

Embodiment 15 provides the system of embodiments 13-14, wherein the bandpass filter is configured to attenuate frequencies away from ω_{RF}.

Embodiment 16 provides a method of detection of electromagnetic fields, the method including the steps of: (a) providing a first beam in a first direction through a vapor cell, the first beam being a probe beam, the first beam having a frequency ωₚ; (b) providing a second beam in a second direction through the vapor cell, the second beam being a dressing beam, the second beam having a frequency ω_{d}; (c) providing a third beam in the second direction through the vapor cell, the third beam being a coupling beam, the third beam having a frequency ω_{c}, the third beam being coaxial with both the first beam and the second beam; (d) frequency stabilizing the first beam, the second beam, and the third beam to successive stepwise resonant transitions resulting in the excitation of a Rydberg state; (e) applying a modulation electric field at frequency ωₘ to the vapor cell using electrodes; (f) beating together all optical frequencies contained in the probe beam after transiting through the vapor cell, by focusing it onto a photodiode; (g) demodulating a photodiode signal at ωₘ; and (h) determining an electromagnetic field near the vapor cell.

Embodiment 17 provides the method of embodiment 16, wherein the demodulating of step (g) uses a lock-in amplifier.

Embodiment 18 provides system for detection of electromagnetic fields (e.g., configured to implement any of the methods of embodiments 1-12 and/or embodiments 16-17), the system including: a first laser source configured to provide a first beam, the first beam being a probe beam; a second laser source configured to provide a second beam, the second beam being a dressing beam; a third laser source configured to provide a third beam, the third beam being a coupling beam; a vapor cell, the vapor cell being configured to contain a gaseous alkali element; a first dichroic mirror configured to combine the second beam and the third beam; a second dichroic mirror configured to allow the first beam to pass through, while reflecting the second beam and the third beam; a third dichroic mirror configured to allow the second beam and the third beam to pass through while reflecting the first beam; and a plurality of signal processing components configured to analyze an electrical signal of the first beam, the plurality of signal processing components including a lock-in amplifier.

Embodiment 19 provides the system of embodiment 18, further including an electrode configured to provide a modulation electric field to the vapor cell.

Embodiment 20 provides the system of any one of embodiments 18-19, further including another electrode configured to provide a modulation electric field to the vapor cell; wherein the first electrode is disposed on a first side of the vapor cell; wherein the second electrode is disposed on a second side of the vapor cell, the second side being opposite the first side.

Embodiment 21 provides the system of any one of embodiments 18-20, further including a first set of electrodes disposed on opposing sides of the vapor cell; a second set of electrodes disposed on opposing sides of the vapor cell; a third set of opposing electrodes disposed on opposing sides of the vapor cell; wherein the first set of electrodes, the second set of electrodes, and the a third set of electrodes are configured for simultaneously applying three mutually perpendicular electric fields, wherein each set of electrodes can be modulated at a unique frequency.

Embodiment 23 provides a method of detecting an electromagnetic field, including the steps of: (a) transferring a frequency modulation to a probe beam via atom-mediated interactions involving excitation of a Rydberg state; (b) mixing optical frequencies contained in the probe beam after the probe beam traverses a vapor cell by focusing the probe beam onto a photodiode; (c) producing a resulting beat note via the photodiode; and (d) demodulating the resulting beat note at the modulation frequency to produce a receiver signal to show sensitivity to low-frequency electric field sampled by the atoms in the vapor cell.

Embodiment 24 provides the method of embodiment 23, wherein the method is implemented using the system of any one of embodiments 13-15 and 18-20.

Embodiment 25 provides the method of any one of embodiments 23-23, wherein the method further includes one or more steps (or features) of any one or more of embodiments 1-12 and 16-17.

### EQUIVALENTS

Although preferred embodiments of the invention have been described using specific terms, such description is for illustrative purposes only, and it is to be understood that changes and variations may be made without departing from the spirit or scope of the following claims.

### INCORPORATION BY REFERENCE

The entire contents of all patents, published patent applications, and other references cited herein are hereby expressly incorporated herein in their entireties by reference.

1. A method of detection of electromagnetic fields, the method comprising the steps of:
(a) providing a first beam in a first direction through a vapor cell, the first beam being a probe beam, the first beam having a frequency ωₚ;
(b) providing a second beam in a second direction through the vapor cell, the second beam being a dressing beam, the second beam having a frequency ω_{d};
(c) providing a third beam in the second direction through the vapor cell, the third beam being a coupling beam, the third beam having a frequency ω_{c}, the third beam being coaxial with both the first beam and the second beam;
(d) frequency stabilizing the first beam, the second beam, and the third beam to successive stepwise resonant transitions resulting in the excitation of a Rydberg state;
(e) applying symmetrical radio frequency (RF) sidebands to the third beam, the symmetrical RF sidebands with frequency spacing ω_{RF} from ω_{c};
(f) coherently transferring the symmetrical RF sidebands to the first beam via a nonlinear wave mixing in the vapor cell; and
(g) determining an electromagnetic field inside the vapor cell.

2. The method of claim 1 wherein, prior to step (g), the method further comprises the steps of:
(h) interfering the frequency components of the first beam after it passes through the vapor cell, ωₚ, ωₚ-ω_{RF}, and ωₚ+ω_{RF}, by focusing the beam on a fast photodiode; and
(i) producing a beat note having a phase.

3. The method of claim 2 wherein, prior to step (g), the method further comprises the step of:
(j) measuring the phase of the beat note.

4. The method of claim 3 wherein the beat note is processed by a bandpass filter, an RF amplifier, and a demodulator.

5. The method of claim 4 wherein the step of determining of step (g) includes recording a Modulation Transfer Spectroscopy (MTS) signal, the MTS signal being an output of the demodulator, and computing a Fast Fourier Transform of the MTS signal to visualize the frequency spectrum.

6. The method of claim 5 wherein the step of determining of step (g) includes processing individual frequency components used as carriers for encoded information.

7. The method of claim 1 wherein the step of determining of step (g) includes adjusting for a Faraday shielding effect from a conductive layer of an element within the vapor cell.

8. The method of claim 1 wherein the vapor cell includes an element in a gaseous state, the element being alkali atoms.

9. The method of claim 1 wherein the vapor cell includes an element in a gaseous state, the element being selected from the group consisting of: lithium, sodium, potassium, rubidium, and cesium.

10. The method of claim 1 wherein the vapor cell includes an element in a gaseous state, the element being rubidium.

11. The method of claim 1 wherein photons are coherently emitted at θₚ-ω_{RF} and ωₚ+ω_{RF}.

12. The method of claim 1 wherein the nonlinear wave mixing of step (f) is a 6-wave mixing (6 WM).

13. A system for detection of electromagnetic fields configured to implement the method, the system comprising:
a first laser source configured to provide a first beam, the first beam being a probe beam;
a second laser source configured to provide a second beam, the second beam being a dressing beam;
a third laser source configured to provide a third beam, the third beam being a coupling beam;
a vapor cell, the vapor cell being configured to contain a gaseous alkali element;
a first dichroic mirror configured to combine the second beam and the third beam;
a second dichroic mirror configured to allow the first beam to pass through, while reflecting the second beam and the third beam;
a third dichroic mirror configured to allow the second beam and the third beam to pass through while reflecting the first beam; and
a plurality of signal processing components configured to analyze an electrical signal of the first beam.

14. The system of claim 13 wherein the plurality of signal processing components includes:
a focusing lens for focusing the first beam;
a fast photodiode for producing a beat note;
a bandpass filter for filtering undesired frequencies of the electrical signal of the first beam;
a RF amplifier for amplifying a portion of the electrical signal of the first beam; and
a demodulator for measuring the instantaneous phase of the beat note.

15. The system of claim 14 wherein the bandpass filter is configured to attenuate frequencies away from ω_{RF}.

16. A method of detection of electromagnetic fields, the method comprising the steps of:
(a) providing a first beam in a first direction through a vapor cell, the first beam being a probe beam, the first beam having a frequency ωₚ;
(b) providing a second beam in a second direction through the vapor cell, the second beam being a dressing beam, the second beam having a frequency ω_{d};
(c) providing a third beam in the second direction through the vapor cell, the third beam being a coupling beam, the third beam having a frequency ω_{c}, the third beam being coaxial with both the first beam and the second beam;
(d) frequency stabilizing the first beam, the second beam, and the third beam to successive stepwise resonant transitions resulting in the excitation of a Rydberg state;
(e) applying a modulation electric field at frequency ωₘ to the vapor cell using electrodes;
(f) beating together all optical frequencies contained in the probe beam after transiting through the vapor cell, by focusing it onto a photodiode;
(g) demodulating a photodiode signal at ωₘ; and
(h) determining an electromagnetic field near the vapor cell.

17. The method of claim 16, wherein the demodulating of step (g) uses a lock-in amplifier.

18. A system for detection of electromagnetic fields, the system comprising:
a first laser source configured to provide a first beam, the first beam being a probe beam;
a second laser source configured to provide a second beam, the second beam being a dressing beam;
a third laser source configured to provide a third beam, the third beam being a coupling beam;
a vapor cell, the vapor cell being configured to contain a gaseous alkali element;
a first dichroic mirror configured to combine the second beam and the third beam;
a second dichroic mirror configured to allow the first beam to pass through, while reflecting the second beam and the third beam;
a third dichroic mirror configured to allow the second beam and the third beam to pass through while reflecting the first beam; and
a plurality of signal processing components configured to analyze an electrical signal of the first beam, the plurality of signal processing components including a lock-in amplifier

19. The system of claim 18, further comprising an electrode configured to provide a modulation electric field to the vapor cell.

20. The system of claim 19, further comprising another electrode configured to provide a modulation electric field to the vapor cell;
wherein the first electrode is disposed on a first side of the vapor cell;
wherein the second electrode is disposed on a second side of the vapor cell, the second side being opposite the first side.

21. The system of claim 18, further comprising:
a first set of electrodes disposed on opposing sides of the vapor cell;
a second set of electrodes disposed on opposing sides of the vapor cell;
a third set of opposing electrodes disposed on opposing sides of the vapor cell;
wherein the first set of electrodes, the second set of electrodes, and the a third set of electrodes are configured for simultaneously applying three mutually perpendicular electric fields,
wherein each set of electrodes can be modulated at a unique frequency.
